(19) United States
(12) Patent Application Publication
(10) Pub. No.: US 2009/0183098 A1
(43) Pub. Date: Jul. 16, 2009

(54) Configurable Keyboard

(75) Inventors: Mark A. Casparian, Miami, FL (US); Reginald I. Rego, Miami, FL (US); Frank C. Azor, Miami, FL (US); Antonios T. Berry, Miami, FL (US); Brian P. Cooper, Miami, FL (US)

Correspondence Address: LARSON NEWMAN ABEL & POLANSKY, LLP, 5914 WEST COURTYARD DRIVE, SUITE 200, AUSTIN, TX, 78730, US

(73) Assignee: DELL PRODUCTS, LP, Round Rock, TX (US)

(21) Appl. No.: 12/013,707

(22) Filed: Jan. 14, 2008

(51) Int. Cl. G06F 3/048; G06F 3/02; H03M 11/00

(52) U.S. Cl. 715/765; 715/810; 715/773; 715/769; 345/172; 341/23; 345/173

(57) ABSTRACT

An information handling system provides a graphical user interface for customization of a keyboard layout. Individual key sizes, shapes, icons, functions, and other characteristics can be created via the GUI. The customized layout can be stored at the information handling system in a file. The file can be accessed to create a keyboard at a touch-screen device based on the customized layout.

### FIELD OF THE DISCLOSURE

This disclosure relates generally to information handling systems, and more particularly to keyboards for information handling systems.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements can vary between different applications, information handling systems can also vary regarding what information is handled, how the information is handled, how much information is processed, stored, or communicated, and how quickly and efficiently the information can be processed, stored, or communicated. The variations in information handling systems allow for information handling systems to be general or configured for a specific user or specific use such as financial transaction processing, airline reservations, enterprise data storage, or global communications. In addition, information handling systems can include a variety of hardware and software components that can be configured to process, store, and communicate information and can include one or more computer systems, data storage systems, and networking systems.

A typical interface device associated with an information handling system is a keyboard. The keyboard allows a user to enter text and other information to control the information handling system and interface with applications executing at the system. However, the keyboard typically has physically fixed position keys that incorporate physically fixed keycap shapes. This provides human factors limitations as the keys must be located in fixed positions and a fixed shape size to accommodate the general average population's finger sizes (length and girth), pitch between fingers, and natural hand/wrist rotation.

Some keyboards (e.g. the Ergodex® DX1) allow a user to physically move a mechanical key switch using an adhesive backing. This can provide an undesirable limitation, because a user must physically modify the positions of the keys and re-teach the computer each of the new key placements and what characters or macros they represent. The user may also have to put a new adhesive-backed label on the keycap to represent the new character it is supposed to represent (a problem if it is supposed to represent a tool or device in a particular application.

Other keyboards (e.g. the Optimus Maximus keyboard) incorporate a display on each keycap thereby allowing the label of each keycap to be dynamically changed according to a saved keyboard profile. However, the limitation of this is that the physical locations of each key, key cap shape and size, pitch between keys and rotational-orientation (if any) of each key has been predetermined and is non-modifiable. Accordingly, a new keyboard device would be useful.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 illustrates a block diagram of an information handling system according to one embodiment of the present disclosure.

FIG. 2 is a diagram of a graphical user interface according to one embodiment of the present disclosure.

FIG. 3 is a diagram of a graphical user interface according to another embodiment of the present disclosure.

FIG. 4 is a block diagram of a touch-screen device according to one embodiment of the present disclosure.

FIG. 5 is a flow diagram of a method of displaying a keyboard according to one embodiment of the present disclosure.

FIG. 6 is a flow diagram of a method of displaying a keyboard according to another embodiment of the present disclosure.

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other teachings can certainly be utilized in this application. The teachings can also be utilized in other applications and with several different types of architectures such as distributed computing architectures, client/server architectures, or middleware server architectures and associated components.

For purposes of this disclosure, an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system can be a personal computer, a PDA, or any other suitable device and can vary in size, shape, performance, functionality, and price. The information handling system can include memory, one or more processing resources such as a central processing unit (CPU) or hardware or software control logic. Additional components of the information handling system can include one or more storage devices, one or more communications ports for communicating with external devices as well as various input and output (I/O) devices, such as a keyboard, a mouse, and a video display. The information handling system can also include one or more buses operable to transmit communications between the various hardware components.

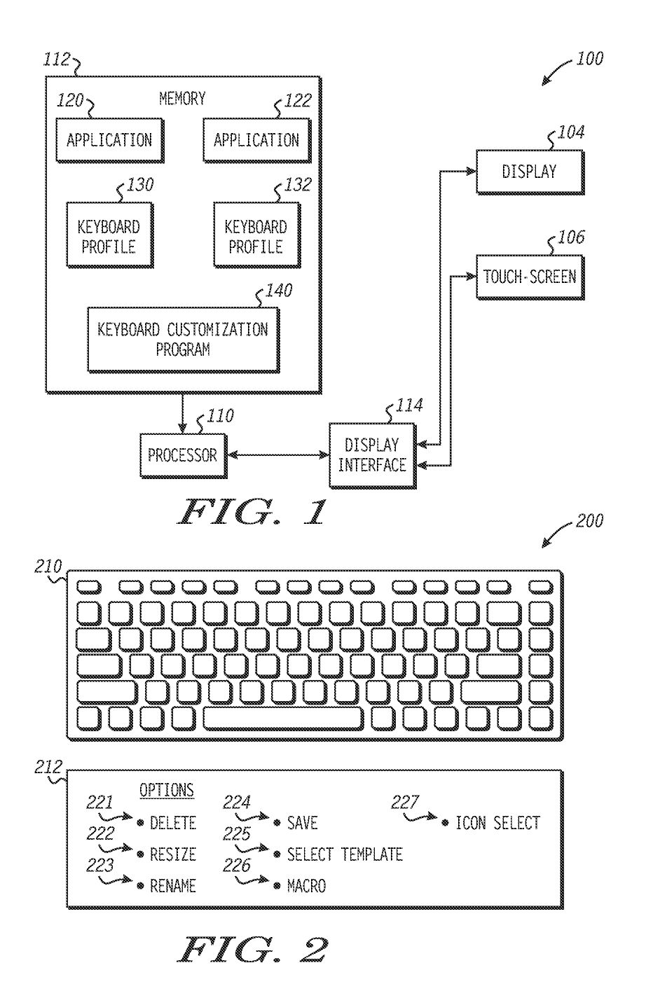

FIG. 1 illustrates a block diagram of an exemplary embodiment of an information handling system, generally designated at 100. In one form, the information handling system 100 can be a computer system such as a personal computer. As shown in FIG. 1, the information handling system 100 can include a first physical processor 110 and a memory 112. In an embodiment, the information handling system 100 can support multiple processors and can allow for simultaneous processing of multiple processors and support the exchange of information within the system.

The memory 112 can be a volatile memory, such as a random access memory (RAM), or non-volatile memory such as flash memory or a hard disk. The memory 112 is configured to store application programs, such as application 120, application 122, and keyboard customization program 140, and data files, such as keyboard profile 130 and keyboard profile 132. In another embodiment, the keyboard profiles 130 and 132 and the keyboard customization program 140 can be stored in a memory resident at the touch-screen display unit 106, thereby allowing a user to take the touch-screen display to another computer and have it operational using the keyboard profiles stored on the portable memory device.

The information handling system 100 also includes a display interface 114 that connects to the processor 110. The display interface 114 provides video display information to a display unit 104 and a touch-screen display unit 106. In an embodiment, the display interface 114 can be configured to provide independent video display information to each device, so that the display unit 104 and the touch-screen display unit 106 display different information. In addition, the display interface 114 can receive information from the touch-screen display unit 106 indicative of user input at the screen, and provide the information to the processor 110.

The touch-screen display unit 106 is configured to provide input information to the display interface 114 based on a user touching the unit. In an embodiment, the touch-screen display unit 106 can incorporate E-field or other sensors to allow a user to interact with the unit without touching the screen, such as through hand gesture recognition. In another embodiment, the touch-screen 106 is a multi-touch interface, providing input information based upon the movements of more than one digit or hand of a user.

In operation, the processor 110 executes computer instructions embodied in the computer readable medium represented by the memory 112. For example, each of the applications 120 and 122 include instructions to manipulate the processor 110 to perform one or more functions, such as word processing, presentation of a game, and the like. The keyboard customization program 140 includes instructions to manipulate the processor 110 to provide a graphical user interface for customization of a keyboard layout. As used herein, the term “keyboard layout” refers to characteristics of a keyboard design, such as relative position of keys, key size, key shape, key rotational-orientation, the number or selection of keys used for the particular profile, key color, background image for the keyboard, key function, text or graphical icon associated with each key, enablement of user feedback per key touch such as audible and haptics feedback, and the like.

In operation, the keyboard customization program 140 provides an interface for keyboard customization via the display 104 and/or the touch-screen display unit 106. In one method of embodiment, a keyboard layout is displayed via the display 104 and the layout can be manipulated via the touch-screen display unit 106 by a user. Thus, the user can change the arrangement of keys in the keyboard, change the shape, size, rotational-orientation, color of individual keys, assign alphanumeric characters, names or graphic icons to keycaps, assign particular functions to keys, place a background image on the layout, provide for a particular type or intensity of feedback (e.g. audible or haptic feedback) and otherwise manipulate the keyboard layout.

Individual keyboard layouts can be stored in keyboard profiles, such as keyboard profile 130 and keyboard profile 132. Thus, the keyboard customization program 140 can provide an option to save a particular layout. In response to the selection of this option, the keyboard customization program 140 instructs the processor 110 to store information representative of the created layout in a keyboard profile.

The keyboard profiles 130 and 132 are accessed by the touch-screen display unit 106 to display the customized keyboard layouts. Accordingly, in response to a request for a particular layout, the touch-screen display unit 106 requests the processor 110 to access the keyboard profile associated with the requested layout. The processor 110 accesses the keyboard profile and provides information to the touch-screen display unit 106 to display the customized layout. The displayed layout is a functional keyboard. Accordingly, as a user presses a displayed key, the touch-screen display unit 106 sends information, such as an input value, to the processor 110 indicating the pressed key. The processor 110 determines the function associated with the key based on the keyboard profile associated with the displayed keyboard, and executes the function. The function will typically depend on the application being executed by the processor 110 when the key is pressed. Thus, the function can include displaying text associated with the key, or performing a more complex function, such as saving a file, copying text to a clip-board, performing a game-related function such as firing a weapon, and the like.

In addition, particular keyboard profiles can be associated with particular applications. Accordingly, when an application is executed by the processor 110, a keyboard based on the associated keyboard profile can be displayed at the touch-screen display unit 106. To illustrate, the application 120 can be associated with the keyboard profile 130 and the application 122 associated with the keyboard profile 132. When the processor 110 executes instructions of the application 120, the keyboard layout associated with the keyboard profile 130 will be displayed at the touch-screen display unit 106. Similarly, when the processor 110 executes instructions of the application 122, the keyboard layout associated with the keyboard profile 132 will be displayed at the touch-screen display unit 106. Further, if the applications 120 and 122 are executing concurrently, such as in two different windows, the displayed keyboard layout at the touch-screen display unit 106 can change as the window of each application is selected.

By associating particular keyboard layouts with particular applications, the keyboard layout can be customized for each application. For example, the application 120 can be a game of a particular type, such as a first-person shooter, while the application 122 can be a game of another type, such as a role-playing game. The keyboard profile 130 for the application 120 can provide a layout customized for a shooter game, and include keys strategically placed for fastest and most comfortable triggering, removal of unused keys to help reduce or eliminate accidental triggering of a wrong key, and within easy reach of the user's unique finger size & girth without having to move one's hand out of gaming position. In contrast, the keyboard profile 132 for the application 132 can provide a layout customized for a role-playing game, providing keys strategically placed or organized such as in groups or quadrants, that allow quick access to spells, inventory, weapon changes, character interactions, and the like. By allowing for customized keyboards for different applications, the user's experience with the application can be enhanced. Further, the user can tailor the keyboard layout according to how that particular user interacts with a program.

FIG. 2 illustrates a diagram of a particular embodiment of a graphical user interface (GUI) 200 provided by the keyboard layout customization program 140. This GUI 200 may be displayed on either the display 104 or the touch-screen display unit 106. The GUI 200 may include a template 210 and layout options 212, including options 221-227. The template 210 provides a keyboard layout template that can be manipulated via the GUI 200. In an embodiment, individual keys in the template 210 can be arranged in a drag-and-drop fashion to change the relative position of the keys. The keys can be dragged with a computer mouse or with single or multi-touch gestures on a touch-screen. In another embodiment, instead of a template, keys are dragged and dropped into position, then using the options 212, the user may manipulate the keys according to user preference.

The options 212 provide options to change the template 210 or manipulate keys placed into position. Each of the options 212 can be selected by actuating the option with a computer mouse or via interaction with a touch-screen. Further, actuation of an option may cause presentation of additional options in a menu format. Each of the options 212 performs a different function associated with the template 210. To illustrate, the delete option 221 removes a selected key from the template 210. Thus, a user can eliminate little-used or otherwise unwanted keys from the template 210.

The resize option 222 allows a user to resize the entire template 210, or individual keys within the template. Keys can be resized by dragging key edges with a mouse or via a touch interface. Touch gestures may also be used to identify an area, either via multiple points of simultaneous contact identifying the outlying perimeter around the desired multiple keys (or multiple objects) to resize at once, or via a finger circling or outlining gesture that encompasses the solid area around the desired keys (or objects) of interest that are to be resized at one time.

The rename option 223 allows a user to assign particular alphanumeric characters or names to each key. In an embodiment, when the keyboard layout is displayed via the touch-screen display unit 106, the assigned name will be displayed on the associated key. This allows a user to assign names which identify particular functions of the associated key.

The save option 224 allows the user to save a customized keyboard layout in a keyboard profile in the memory 112. Accordingly, in response to selection of this option the processor 110 saves the layout as represented by the template 210, including any changes made by the user, in a keyboard profile. The save option 224 can also allow the user to associate the keyboard profile with one or more applications, so that when those applications are invoked, the respective keyboard layout/profile will be displayed at the touch-screen display unit 106.

The select template option 225 allows a user to select a starting template from a particular keyboard layout. In an embodiment, the templates can be customized and saved by a user, allowing the user to efficiently create variations on a particular template.

The macro option 226 allows the user to assign particular functions to particular keys. Such functions can include one or more functions associated with other keys, or functions associated with a particular application. Further, the macro option 226 allows a user to assign a sequence of functions to a particular key. Accordingly, when a key associated with a sequence of functions is actuated via the touch-screen display unit 106, the processor 110 executes, based on an input value associated with that key, the function sequence. For example, the macro option 226 can be used to associate a string of functions in a first-person shooter application with a particular key. When the key is pressed during execution of the game, the processor 110 ensures that the sequence of functions is executed. This allows a user of a particular application to execute complex function sequences with fewer keystrokes, improving the user's efficiency with an application.

The icon select option 227 allows a user to associate a particular icon with a key. This icon can be displayed on the keycap when the keyboard layout is displayed at the touch-screen display unit 106. The icons can be selected from a pre-defined icon set, or created by the user via a graphics program. Accordingly, the icon select option allows the user to create a keyboard where certain keys display the function of the key rather than just a name—for example one key may display a weapon on the keycap rather than displaying an alphanumeric character. Visualization of functions on the keycaps can thus enhance the user experience.

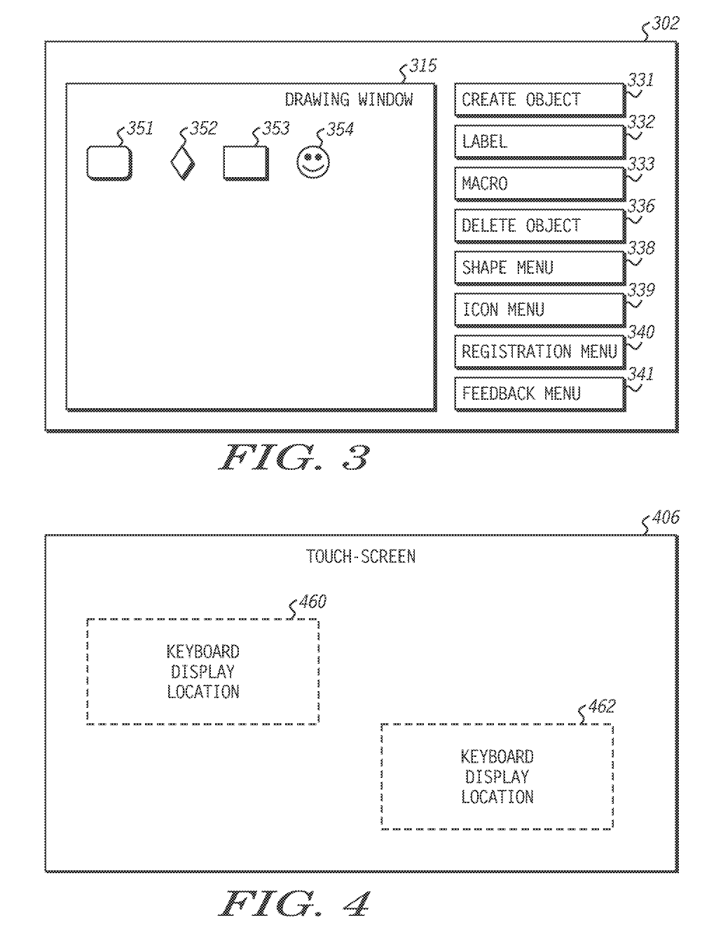

Referring to FIG. 3, a diagram of a particular embodiment of a GUI 302 that can be provided by the keyboard customization program 140 is illustrated. The GUI 302 includes a drawing window 315 and options 331-339. The drawing window 315 displays the keyboard layout, while the options 331-339 provide different options to enable creation and manipulation of the layout, including keys 351-354. In another embodiment, the GUI is initiated at the touch-screen display unit 106 upon recognition of a particular single-touch or multi-touch gesture, or non-contact based hand gesture recognition (as based on current art E-field change detection and tracking technology). The GUI includes the drawing window 315 and options 331-339.

The create object option 331 allows a user to create individual keys in the keyboard layout. In an embodiment, the create object option 331 allows a user to draw in a freehand fashion, with a computer mouse, stylus or finger, using a touch interface, and the like. This allows the user to create highly customized and configurable key shapes.

The label option 332 allows the user to assign particular labels, such as text strings, to particular keys. In an embodiment the assigned labels will be displayed with the associated keys when the layout is displayed at the touch-screen 106.

The macro option 333 allows a user to assign particular functions and function sequences to particular keys, as described above with respect to FIG. 2.

The delete object option 336 allows a user to delete particular keys, selected via touch or mouse, from a layout.

The shape menu option 338 provides a set of pre-defined shapes for keys which the user can drag and drop into position in the drawing window 315. Upon selection, the shape is displayed in the drawing window 315. The shape can then be manipulated, including changing the position of the key relative to other keys, changing the size of the key, and the like.

The icon menu option 339 allows a user to assign particular graphic files or icons to a key, as described above with respect to FIG. 2.

The registration menu option 340 allows a user to designate particular keys as associated with particular fingers. Accordingly, in response to a user placing his hand on the touch-screen display unit 106, the unit can automatically align the display of the keyboard according to the keys registered for each finger. In an embodiment, the touch-screen display unit will align the keyboard display in response to a particular gesture, such as forceful placement of five fingers of one hand on the unit.

The feedback menu option 341 allows a user to assign a feedback attribute to a key (or keys). The choices can include the provision for a particular type of feedback (e.g., audible or haptics feedback) and a particular feedback intensity when the selected key or keys are touched.

Referring to FIG. 4, a diagram particular embodiment of a touch-screen display unit 406, corresponding to the touch-screen display unit 106 of FIG. 1, is illustrated. The touch-screen display unit 406 can display a keyboard layout, based on the associated keyboard profile, in a number of locations, such as display locations 460 and 462. This allows the user to orient placement of the keyboard layout in a convenient manner for use. In an embodiment, a user can change the position of the keyboard layout in a drag-and-drop fashion, thus allowing flexible positioning of the layout.

In another embodiment, the touch-screen display unit 406 can dynamically determine placement or registration of the keyboard layout based on a one-hand-5 finger gesture. To illustrate, when a user places all 5 fingers of one hand on the touch-screen display unit 406, the touch sensor processes and identifies this 5 finger gesture as a user's request for assistance. The processor 110 evaluates where the keyboard layout currently is, compares it to the location of the current hand registration. The processor then calculates how much of a x and y coordinate change or shift should occur on the touch-screen display unit 406, and graphically shifts the keyboard layout position on the display such that the correct keys re-register under the hand. As a result, if a user is playing a game, perhaps with lots of high chaotic action and recognizes their hands slipped out of position, they can quickly and forcefully place one hand with all 5 fingers touching the screen, the keyboard layout with automatically be re-aligned under the users hand, based on the correct registration of the designated middle finger/key assignment without the user having to take their eyes off the monitor.

Referring to FIG. 5, a flow diagram of a particular embodiment of a method of displaying a keyboard is illustrated. At block 502, a graphical user interface is provided that allows customization of a keyboard layout. In an embodiment, the GUI can be one of the interfaces described with respect to FIGS. 2 and 3. At block 504, a layout associated with the customized keyboard is stored in a keyboard profile based on the options selected via the GUI.

At block 506, a processor determines that an application has been selected. In response, at block 508 the processor determines which keyboard profile is associated with the accessed application and accesses the file. In particular, the processor provides information representative of a keyboard layout based on the accessed file to a touch-screen device. At block 510, the keyboard is displayed at the touch-screen based on the information provided by the processor. Accordingly, the displayed keyboard will correspond to the customized layout created via the GUI. At block 512, input values are received by the processor from the touch-screen based on a user pressing keys of the displayed keyboard.

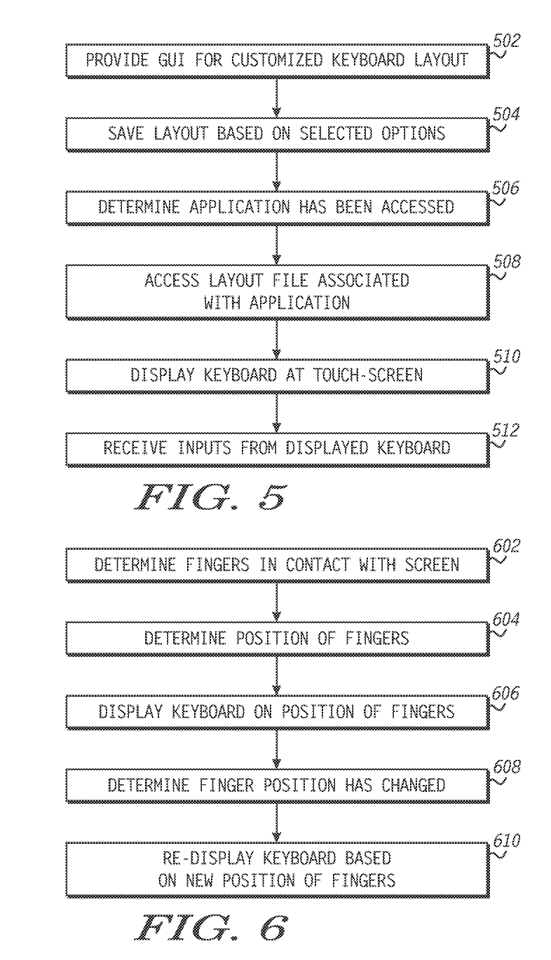

Referring to FIG. 6, a flow diagram of a particular embodiment of a method of displaying a keyboard at a touch-screen device is illustrated. At block 602, it is determined that a user has placed his finger(s) in contact with the touch-screen. In an embodiment, a keyboard is not displayed until it is determined a minimum number of fingers of one or both hands (e.g. five) have been placed on the touch-screen. At block 604, the touch-screen determines the position of the user's fingers relative to the available display space. At block 606 the touch-screen displays a keyboard based on the position of the user's fingers. In an embodiment, the touch-screen displays the keyboard such that a default set of keys are placed under the fingers touching the screen.

At block 608, the touch-screen determines that the position of the user's fingers has changed, indicating the user has moved his hand over the touch-screen. In response, at block 610, the touch-screen re-displays the keyboard based on the new position of the fingers. Accordingly, the keyboard follows the position of the user's fingers on the touch-screen, improving the flexibility of the screen and the user's interactions with an information handling device.

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A method, comprising:
displaying via a graphical user interface (GUI) a set of options for customization of a keyboard layout;
receiving via the GUI first information representing a first customized keyboard layout; and
storing the first information.

2. The method of claim 1, further comprising:
receiving via the GUI second information representing a second customized keyboard layout; and
storing the second information.

3. The method of claim 2, further comprising:
displaying a first keyboard based on the first information in response to an indication that a first application has been accessed; and
displaying a second keyboard based on the second information in response to an indication that a second application has been accessed.

4. The method of claim 1, further comprising:
displaying a first keyboard based on the first information at a touch-screen device.

5. The method of claim 4, further comprising:
receiving an indication that a first key of the first keyboard has been actuated;
determining an input value associated with the first key; and
providing an indication of the input value to an application.

6. The method of claim 5, wherein the input value is representative of a sequence of functions associated with the application.

7. The method of claim 1, wherein displaying the set of options comprises:
displaying a set of keys; and
providing a drag-and-drop interface configured to change a position of one of the set of keys relative to a second of the set of keys.

8. The method of claim 7, wherein providing the drag-and-drop interface comprises providing the drag-and-drop interface via a touch-screen device.

9. The method of claim 1, wherein displaying the set of options comprises:
displaying a set of keys; and
providing an interface to change a size of one of the set of keys.

10. The method of claim 1, wherein displaying the set of options comprises:
displaying a set of keys; and
providing an interface to associate a name with one of the set of keys.

11. The method of claim 1, wherein displaying the set of options comprises:
displaying a set of keys; and
providing an interface to set a shape of one of the set of keys.

12. The method of claim 1, wherein displaying the set of options comprises:
displaying a set of keys; and
providing an interface to set an input value associated with one of the set of keys.

13. The method of claim 1, further comprising displaying a keyboard at a touch-screen device based on the first information in response to determining a plurality of fingers are in contact with the touch-screen device.

14. The method of claim 13, wherein displaying the keyboard comprises displaying the keyboard based on a position of the plurality of fingers.

15. A computer readable medium comprising a computer program including instructions to manipulate a processor, the instructions comprising instructions to:
display via a graphical user interface (GUI) a set of options for customization of a keyboard layout;
receive via the GUI first information representing a first customized keyboard layout; and
store the first information.

16. The computer readable medium of claim 15, wherein the instructions further comprise instructions to:
display a first keyboard based on the first information in response to an indication that a first application has been accessed; and
display a second keyboard based on the second information in response to an indication that a second application has been accessed.

17. The computer readable medium of claim 15, wherein the instructions further comprise instructions to:
receive an indication that a first key of the first keyboard has been actuated;
determine an input value associated with the first key; and
provide an indication of the input value to an application.

18. The computer readable medium of claim 15, wherein the instructions to display the set of options comprise instructions to:
display a set of keys; and
provide a drag-and-drop interface configured to change a position of one of the set of keys relative to a second of the set of keys.

19. The computer readable medium of claim 15, wherein the instructions to display the set of options comprise instructions to:
display a set of keys; and
provide an interface to change a size of one of the set of keys.

20. The computer readable medium of claim 15, wherein the instructions to display the set of options comprise instructions to:
display a set of keys; and
provide an interface to associate a name with one of the set of keys.
